(19) United States
(12) Patent Application Publication
(10) Pub. No.: US 2007/0121775 A1
(43) Pub. Date: May 31, 2007

(54) Memory controller and method thereof

(75) Inventors: Yu-Kuo Chen, Taipei City (TW); Hsin-Chuan Chen, Taipei City (TW)

Correspondence Address: RABIN & Berdo, PC, 1101 14TH STREET, NW, SUITE 500, WASHINGTON, DC, 20005, US

(73) Assignee: Prolific Technology Inc., Taipei (TW)

(21) Appl. No.: 11/606,004

(22) Filed: Nov. 30, 2006

(30) Foreign Application Priority Data
Nov. 30, 2005 (TW) 94142189

(51) Int. Cl. H03D 3/24

(52) U.S. Cl. 375/376

(57) ABSTRACT

A memory controller and method thereof are provided. The memory controller includes a control logic circuit, a phase locked loop (PLL) and a multiplexer. The PLL generates a plurality of phase clock signals according to a system clock signal. The phase clock signals have the same frequency with the system clock. The phase clock signals have different phase difference to each other. The multiplexer receives the phase clock signals under the control of the control logic circuit, then selects and outputs one of the phase clock signals to generate a selected phase clock signal.

This application claims the benefit of Taiwan application Serial No. 94142189, filed Nov. 30, 2005, the subject matter of which is incorporated herein by reference.

### BACKGROUND OF THE INVENTION

1. Field of the Invention

The invention relates in general to a memory controller and method thereof, and more particularly to a DDR SDRAM memory controller and method thereof.

2. Description of the Related Art

Referring to FIG. 1, a block diagram of a conventional memory controller is shown. The memory controller 100 includes a control logic circuit 110, flip-flops 120 and 130 and buffers 141-143. During data transmission, the contents of the to-be-transmitted data are fetched and transformed into corresponding signals whose periods are delayed to meet the requirements.

The control logic circuit 110 outputs a control signal Co11. The flip-flop 120 receives the control signal Co11 and a system clock signal Clk11 to generate a control signal Co12 to the flip-flop 130. The flip-flop 130 receives the control signal Co12 and a delayed system clock signal Clk12 to generate and output the control signal Co13.

The system clock signal Clk11 passes through the buffers 141-143 to generate the delayed system clock signal Clk12. In terms of a 100 Mhz system clock signal, if the delayed system clock signal Clk12 is delayed by ¼ period, the transmission interval is 2.5 ns (nano second). The delay of the system clock signal is adjusted by the buffer, and is affected by the circuit. Each fine tuning requires accurate simulation and the layout of wire. If the frequency changes to 80 Mhz, the original transmission interval 2.5 ns is no more applicable. Thus, the conventional memory controller can not change frequency arbitrarily.

Referring to FIG. 2, a block diagram of another conventional memory controller is shown. The memory controller 200 differs from the memory controller 100 of FIG. 1 in the method of generating the delayed system clock signal Clk13 inputted into the flip-flop 130. At first, the system clock signal Clk11 passes through the buffers 241-244. Then, the clock signal is delayed and generated by the buffers. After that, the multiplexer 245 selects and outputs the delayed system clock signal Clk13 to the flip-flop 130. Despite the fact that the delay period of the system clock signal is selected by the multiplexer, the accuracy of the delay phase is determined according to the time and the number of the buffer, and the results are not as good as expected. The prior arts are easily affected by factors such as manufacturing process, temperature, and voltage, and the transmission rate can hardly be increased.

### SUMMARY OF THE INVENTION

It is therefore an object of the invention to provide a memory controller and method thereof capable of adjusting the delay phase of a signal to fit system requirements, and adjusting the main frequency according to the change in system requirements without re-setting the delay phase.

The invention achieves the above-identified object by providing a memory controller. The memory controller includes a control logic circuit, a phase locked loop (PLL) and a multiplexer. The PLL generates a plurality of phase clock signals according to a system clock signal. The phase clock signals have the same frequency with the system clock. The phase clock signals have different phase difference to each other. The multiplexer receives the phase clock signals under the control of the control logic circuit, then selects and outputs one of the phase clock signals to generate a selected phase clock signal.

The invention achieves another object by providing a memory controlling method used in a memory controller. Firstly, a plurality of phase clock signals are generated by the PLL according to a system clock signal. The phase clock signals have the same frequency with the system clock signal, but have different phase difference to each other. Thereafter, one of the phase clock signals is selected and outputted to generate a selected phase clock signal.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) shows a block diagram of a conventional memory controller.

FIG. 2 (Prior Art) shows a block diagram of another conventional memory controller.

FIG. 3 shows a block diagram of a memory controller according to a first preferred embodiment of the invention.

FIG. 4 shows a block diagram of a memory controller according to a second preferred embodiment of the invention.

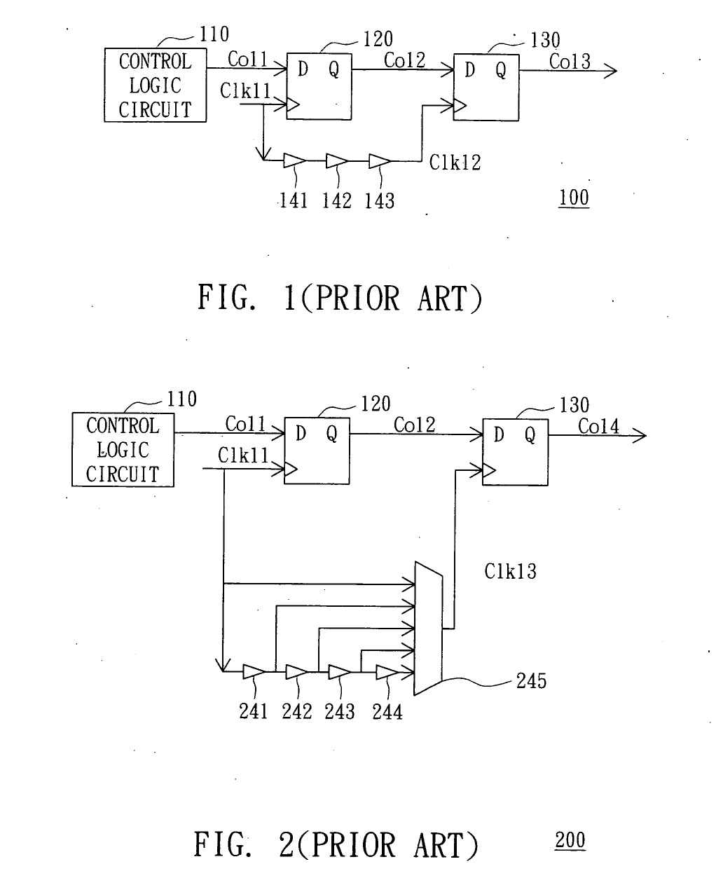

### DETAILED DESCRIPTION OF THE INVENTION

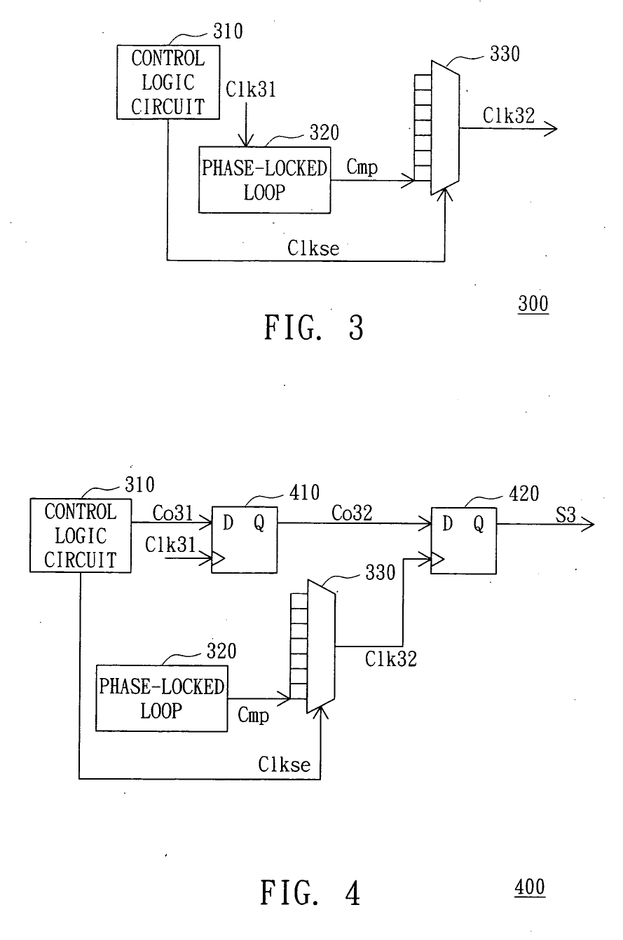

Referring to FIG. 3, a block diagram of a memory controller according to a first preferred embodiment of the invention is shown. The memory controller 300 includes a control logic circuit 310, a phase locked loop (PLL) 320 and a multiplexer 330. The PLL 320 generates a plurality of phase clock signals Cmp according to a system clock signal Clk31. The phase clock signals Cmp have the same frequency with the system clock signal Clk31, and have different phase difference to each other. The multiplexer 330 receives the phase clock signal Cmp under the control of a signal Clkse of the control logic circuit 310, then selects and outputs one of the phase clock signals Cmp to generate a selected phase clock signal Clk32.

The selected phase clock signal Clk32 is used as a clock signal or a strobe signal. The output of the multiplexer 330 is adjusted according to the required delay extent of the clock signal or the required delay period of the strobe signal.

The memory controller 300 is used in a double data rate (DDR) synchronous dynamic random access memory (SDRAM) for example. If the selected phase clock signal Clk32 is used as a strobe signal, according to the requirement of the DDR SDRAM, data are fetched at the middle transferring of the data signal and are delayed by ¼ period than the system clock signal. The data transmission of the DDR SDRAM is activated at the raising edge and falling edge of the system clock signal according to double transition clocking technology, that is, transmission is activated every ½ period. Data are fetched at the middle transferring of the strobe signal, that is, ¼ period.

The DDR SDRAM is the next generation memory configuration of the SDRAM. The comparison between the DDR SDRAM and the SDRAM shows that the transmission rate of the DDR SDRAM doubles that of the SDRAM. If the clock frequency of the SDRAM is 66 Mhz, and the transmission interval is 15 ns (nano second), then the transmission frequency of DDR SDRAM is 133 Mhz, and the transmission interval is 7.5 ns.

According to the DDR SDRAM disclosed above, data are transmitted at both the upper wave band and the lower wave band within the same clock period. Compared with the SDRAM which only transmits data once within the same clock period, the efficiency of the DDR SDRAM doubles that of the SDRAM.

The PLL 320 draws the multi-phases from inside to generate a multi-phase clock signal with the same frequency, that is, the phase clock signal Cmp. In the present embodiment of the invention, there are 8 phase clock signals Cmp respectively delayed from ⅛ period, 2/8 period to ⅞ period. The phase relationship of the PLL 320 remains the same and is not affected by the frequency, and the selected phase clock signal is not affected by the frequency either. The frequency of the phase clock signal Cmp is the same with that of the system clock signal Clk31.

If the frequency of the memory corresponds to the replacement of system or the frequency raises and falls due to environmental factors, the corresponding phase of the signal still remains the same. The system automatically corresponds to the phase that the control signal requires, hence no software is needed to adjust the system.

Referring to FIG. 4, a block diagram of a memory controller according to a second preferred embodiment of the invention is shown. The present embodiment of the invention differs from the previous embodiment in that the present embodiment further includes flip-flops 410 and 420. The flip-flop 410 receives a system clock signal Clk31 and a first signal Co31 of the control logic circuit 310 to output a second signal Co32. The flip-flop 420 receives the second signal Co32 and a selected phase clock signal Clk32 to generate a third signal S3. The third signal S3 is used as a control signal, such as a read signal, a write signal or an address signal.

The memory controller and the method thereof disclosed in the above embodiments of the invention are capable of adjusting the delay phase of a signal to meet system requirements. The main frequency is changed to fit system requirements without re-setting the delay phase. Unlike the prior arts which have to consider the difference in frequency, the invention changes the delay time of signal without having to consider the difference in frequency.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A memory controller, comprising:
a control logic circuit;
a phase locked loop (PLL) for generating a plurality of phase clock signals according to a system clock signal, wherein the phase clock signals have the same frequency with the system clock signal, but have different phase difference to each other; and
a multiplexer for receiving the phase clock signals, wherein the multiplexer selects and outputs one of the phase clock signals under the control of the control logic circuit to generate a selected phase clock signal.

2. The controller according to claim 1, wherein the selected phase clock signal is used as a clock signal.

3. The controller according to claim 1, wherein the selected phase clock signal is used as a strobe signal.

4. The controller according to claim 1, further comprising:
a first flip-flop for receiving the system clock signal and a first signal of the control logic circuit to output a second signal; and
a second flip-flop for receiving the second signal and the selected phase clock signal to generate a third signal.

5. The controller according to claim 1, wherein the third signal is used as a control signal.

6. The controller according to claim 1, being used in a double data rate SDRAM (DDR SDRAM).

7. A memory controlling method used in a memory controller, comprising:
generating a plurality of phase clock signals by a PLL according to a system clock signal, wherein the phase clock signals have the same frequency with the system clock signal, but have different phase difference to each other; and
selecting and outputting one of the phase clock signals to generate a selected phase clock signal.

8. The controlling method according to claim 7, wherein the selected phase clock signal is used as a clock signal.

9. The controlling method according to claim 7, wherein the selected phase clock signal is used as a strobe signal.

10. The controlling method according to claim 7, wherein the memory controller is used in a DDR SDRAM.
